(19) United States
(12) Patent Application Publication
(10) Pub. No.: US 2007/0045707 A1
(43) Pub. Date: Mar. 1, 2007

(54) Memory device and manufacturing method thereof

(76) Inventor: Szu-Yu Wang, Hsinchu (TW)

Correspondence Address: J C PATENTS, INC., 4 VENTURE, SUITE 250, IRVINE, CA, 92618, US

(21) Appl. No.: 11/217,206

(22) Filed: Aug. 31, 2005

(51) Int. Cl. H01L 29/76

(52) U.S. Cl. 257/314

(57) ABSTRACT

A memory device comprising a substrate, a first insulation layer, a charge storage layer, a second insulation layer, a gate electrode layer and source/drain regions is provided. The forbidden gap of the substrate is larger than the forbidden gap of silicon. The first insulation layer is disposed over the substrate. The charge storage layer is disposed over the first insulation layer. The second insulation layer is disposed over the charge storage layer. The gate electrode layer is disposed over the second insulation layer. The gate electrode layer, the second insulation layer, the charge storage layer and the first insulation layer constitute a stacked structure. The source/drain regions are disposed in the substrate adjacent to two sides of the stacked structure.

### BACKGROUND OF THE INVENTION

1. Field of the Invention

The present invention relates to a semiconductor device and a manufacturing method thereof, and more particularly, to a memory device and a manufacturing method thereof.

2. Description of the Related Art

Lately, since functions of computer micro-processors have been improved day by day, amount of data operated and calculated by software is also increased. As a result, expectations for memory devices are in a way higher and higher. In order to fabricate memory devices with high capacities and low costs so as to meet these requirements, it is now the semiconductor manufacturers' aim to produce memory devices with highly integrated density.

Volatile and non-volatile memory devices such as erasable-and-programmable read-only memories (EPROMs), electrically-erasable-programmable read-only memories (E²PROMs), flash memories, and DRAMs can at many times read, write or erase data stored therein. Accordingly, these memory devices have been widely adopted and used in personal computers and electronic equipments.

Generally, a substrate material of a memory device is silicon. Due to a small forbidden gap of silicon, operations of a memory device have the following disadvantages.

If a channel hot electron injection (CHEI) method is used, the small forbidden gap of silicon creates a large energy barrier between the silicon substrate and a tunneling dielectric layer. Electrons or holes must overcome the large energy barrier to enter into the channel layers. As a result, the operational efficiency of the memory device declines.

In addition, if a Fowler-Nordheim tunneling (FN tunneling) method is used to erase data, due to the small forbidden gap of silicon, holes are easily to be generated attributed to the impact ionization effect in the substrate. It also results in the anode hot hole impact effect and damages the tunneling dielectric layer. Accordingly, the reliability of the device is decreased.

### SUMMARY OF THE INVENTION

Accordingly, the present invention is directed to a memory device and a manufacturing method thereof to improve the operational speed of the memory device.

The present invention is also directed to a memory device and a manufacturing method thereof to enhance the reliability of the memory device.

The present invention provides a memory device, which comprises a substrate, a first insulation layer, a charge storage layer, a second insulation layer, a gate electrode layer, and source/drain regions. Wherein, a forbidden gap of the substrate is larger than a forbidden gap of silicon. The first insulation layer is disposed over the substrate. The charge storage layer is disposed over the first insulation layer. The second insulation layer is disposed over the charge storage layer. The gate electrode layer is disposed over the second insulation layer, wherein the gate electrode layer, the second insulation layer, the charge storage layer, and the first insulation layer constitute a stacked structure. The source/drain regions are disposed in the substrate adjacent to two sides of the stacked structure.

According to the memory device of a preferred embodiment of the present invention, a material of the substrate can be, for example, SiₓC₁₋ₓ or SiₓGe_{y}C_{z}.

According to the memory device of a preferred embodiment of the present invention, a material of the substrate can be, for example, GeP, GeAs, ZnSe, CdTe, AlAs, InP, CdS, or GaN.

The present invention provides a method of fabricating a memory device. First, a substrate is provided, wherein a forbidden gap of the substrate is larger than a forbidden gap of silicon. A first insulation layer, a charge storage layer, a second insulation layer, and a gate electrode layer are sequentially formed over the substrate. Wherein, the gate electrode layer, the second insulation layer, the charge storage layer, and the first insulation layer constitute a stacked structure. The source/drain regions are then formed in the substrate adjacent to two sides of the stacked structure.

According to the method of fabricating the memory device of a preferred embodiment of the present invention, a material of the substrate can be, for example, SiₓC₁₋ₓ or SiₓGe_{y}C_{z}.

According to the method of fabricating the memory device of a preferred embodiment of the present invention, a method of forming the substrate can be, for example, a low-pressure chemical vapor deposition (LPCVD) method, a rapid thermal chemical vapor deposition method (RTCVD), a plasma-enhanced chemical vapor deposition (PECVD) method, a microwave chemical vapor deposition method, a laser irradiation decomposition method, a low-temperature molecular beam epitaxy method, or a reactive magnetic sputtering method.

According to the method of fabricating the memory device of a preferred embodiment of the present invention, a material of the substrate can be, for example, GeP, GeAs, ZnSe, CdTe, AlAs, InP, CdS, or GaN.

The present invention provides another memory device, which comprises a semiconductor layer, a substrate, a first insulation layer, a charge storage layer, a second insulation layer, a gate electrode layer, and source/drain regions. The substrate is disposed over the semiconductor layer. Wherein, a forbidden gap of the substrate is larger than a forbidden gap of silicon. The first insulation layer is disposed over the substrate. The charge storage layer is disposed over the first insulation layer. The second insulation layer is disposed over the charge storage layer. The gate electrode layer is disposed over the second insulation layer, wherein the gate electrode layer, the second insulation layer, the charge storage layer, and the first insulation layer constitute a stacked structure. The source/drain regions are disposed in the substrate adjacent to two sides of the stacked structure.

According to the memory device of a preferred embodiment of the present invention, a material of the semiconductor layer can be, for example, Si or Ge.

According to the memory device of a preferred embodiment of the present invention, an insulation layer is disposed between the substrate and the semiconductor layer.

According to the memory device of a preferred embodiment of the present invention, a material of the substrate can be, for example, SiₓC₁₋ₓ or SiₓGe_{y}C_{z}.

According to the memory device of a preferred embodiment of the present invention, a material of the substrate can be, for example, GeP, GeAs, ZnSe, CdTe, AlAs, InP, CdS, or GaN.

The present invention also provides a method of fabricating a memory device. First, a semiconductor layer is provided. A substrate is then formed over the semiconductor layer, wherein a forbidden gap of the substrate is larger than a forbidden gap of silicon. A first insulation layer, a charge storage layer, a second insulation layer, and a gate electrode layer are sequentially formed over the substrate. Wherein, the gate electrode layer, the second insulation layer, the charge storage layer, and the first insulation layer constitute a stacked structure. The source/drain regions are then formed in the substrate adjacent to two sides of the stacked structure.

According to the method of fabricating the memory device of a preferred embodiment of the present invention, a material of the semiconductor layer can be, for example, Si or Ge.

According to the method of fabricating the memory device of a preferred embodiment of the present invention, the method further comprises forming an insulation layer over the semiconductor layer and then forming the substrate over the insulation layer.

According to the method of fabricating the memory device of a preferred embodiment of the present invention, a material of the substrate can be, for example, SiₓC₁₋ₓ or SiₓGe_{y}C_{z}.

According to the method of fabricating the memory device of a preferred embodiment of the present invention, a method of forming the substrate can be, for example, a low-pressure chemical vapor deposition (LPCVD) method, a rapid thermal chemical vapor deposition method (RTCVD), a plasma-enhanced chemical vapor deposition (PECVD) method, a microwave chemical vapor deposition method, a laser irradiation decomposition method, a low-temperature molecular beam epitaxy method, or a reactive magnetic sputtering method.

According to the method of fabricating the memory device of a preferred embodiment of the present invention, a material of the substrate can be, for example, GeP, GeAs, ZnSe, CdTe, AlAs, InP, CdS, or GaN.

Because the substrate material of the present invention has a forbidden gap larger than that of silicon, the energy barrier between the substrate and the first insulation layer of the present invention is smaller. When the memory device is programmed or erased, electrons or holes can be easily injected into the charge storage layer from the substrate, or into the substrate from the charge storage layer. Accordingly, the operational speed of the memory device can be improved.

Further, as the substrate material of the present invention has a forbidden gap larger than that of silicon, the anode hot hole impact effect to the first insulation layer, i.e., the tunneling dielectric layer, can be reduced, while the FN tunneling method is applied to the memory device. The reliability of the memory device is thus enhanced.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a schematic cross sectional view of a memory device according to a preferred embodiment of the present invention.

FIG. 2 is a schematic showing improving the program/erase effect by using memory device with substrate of this invention.

FIGS. 3A-3B are schematic showing preventing the impact ionization effect damages the tunneling dielectric layer by using memory device with the substrate of this invention.

FIGS. 4A-4F are schematic cross sectional drawings showing a process flow of a method of fabricating a memory device according to a preferred embodiment of the present invention.

FIG. 5A is a schematic cross sectional view showing a memory device according to another preferred embodiment of the present invention.

FIG. 5B is a schematic cross sectional view showing a memory device according to a preferred embodiment of the present invention.

FIGS. 6A-6G are schematic cross sectional drawings showing a process flow of a method of fabricating a memory device according to another preferred embodiment of the present invention.

FIGS. 7A-7H are schematic cross sectional drawings showing a process flow of a method of fabricating a memory device according to a preferred embodiment of the present invention.

### DESCRIPTION OF SOME EMBODIMENTS

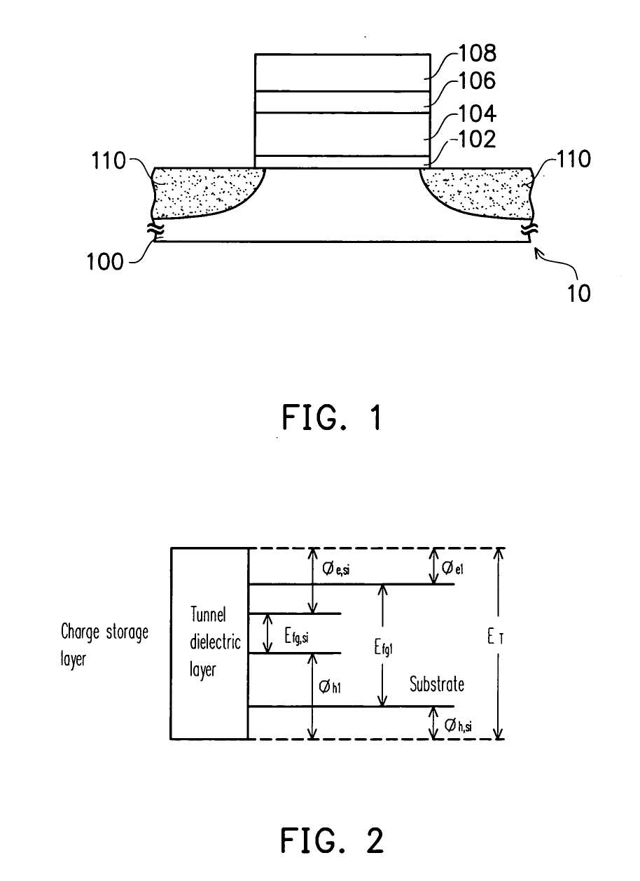

FIG. 1 is a schematic cross sectional view of a memory device according to a preferred embodiment of the present invention. Referring to FIG. 1, the memory device 10 of this embodiment comprises a substrate 100, an insulation layer 102, a charge storage layer 104, an insulation layer 106, a gate electrode layer 108, and source/drain regions 110. In this embodiment, the insulation layer 102 is disposed over the substrate 100. The charge storage layer 104 is disposed over the insulation layer 102. The insulation layer 106 is disposed over the charge storage layer 104. The gate electrode layer 108 is disposed over the insulation layer 106. Wherein, the gate electrode layer 108, the insulation layer 106, the charge storage layer 104, and the insulation layer 102 constitute a stacked structure. The source/drain regions 110 are disposed in the substrate 100 adjacent to two sides of the stacked structure. Note that the forbidden gap of the substrate 100 is larger than that of silicon in this embodiment.

FIG. 2 is a schematic showing improving the program/erase effect by using memory device with substrate of this invention. Referring to FIG. 2, E_{fg,Si} is the forbidden gap of Si substrate, E_{fg1} is the forbidden gap of substrate of this invention, E_{T} is the energy gap of tunnel dielectric layer, φ_{e,Si} is the energy barrier of electron tunneling through tunnel dielectric layer from the Si substrate, φₑ₁ is the energy barrier of electron tunneling through tunnel dielectric layer from the substrate of this invention, φ_{h,Si} is the energy barrier of hole tunneling through tunnel dielectric layer from the Si substrate, φₕ₁ is the energy barrier of hole tunneling through tunnel dielectric layer from the substrate of this invention.

According to the FIG. 2, because of the forbidden gap of substrate of this invention E_{fg1} is larger than the forbidden gap of Si substrate E_{fg,Si}, the energy barrier of electron tunneling through tunnel dielectric layer from the substrate of this invention φₑ₁ is less than the energy barrier of electron tunneling through tunnel dielectric layer from the Si substrate φ_{e,Si}, also the energy barrier of hole tunneling through tunnel dielectric layer from the substrate of this invention φₕ₁ is less than the energy barrier of hole tunneling through tunnel dielectric layer from the Si substrate φ_{h,Si}. Therefore, when the memory device is manufactured with the substrate of this invention, electrons or holes can be easily injected into the charge storage layer from the substrate, the better programming or erasing efficiency is thus achieved.

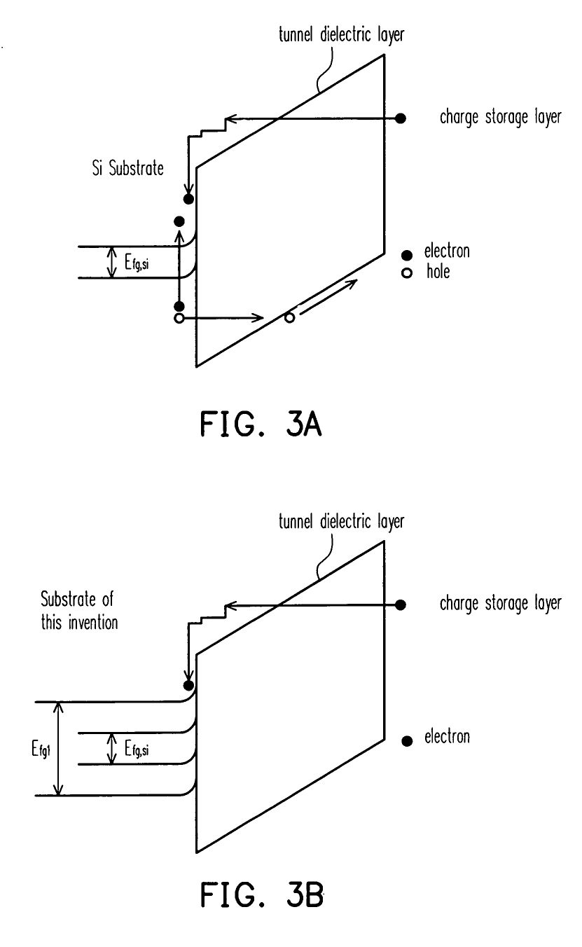

FIGS. 3A-3B are schematic showing preventing the impact ionization effect damages the tunneling dielectric layer by using memory device with substrate of this invention. Referring to FIG. 3A, for the memory device with Si substrate, when a FN tunneling method is used to erase data, impact ionization induced electron-hole pair generation will occur from the injection of such high energy electrons into Si substrate through the tunnel dielectric layer. With the existence of negative gate voltage, the holes will be accelerated toward tunnel dielectric and damage tunnel dielectric integrity.

Referring to FIG. 3B, for the memory device with substrate of this invention, when a FN tunneling method is used to erase data, even the electrons injected into substrate of this invention through the tunnel dielectric layer have high energy, the impact ionization will not easily occur. Therefore the damage on the tunnel dielectric layer will be reduced.

The materials of these film layers of the memory device 10 will be described below accompanying by the process flow.

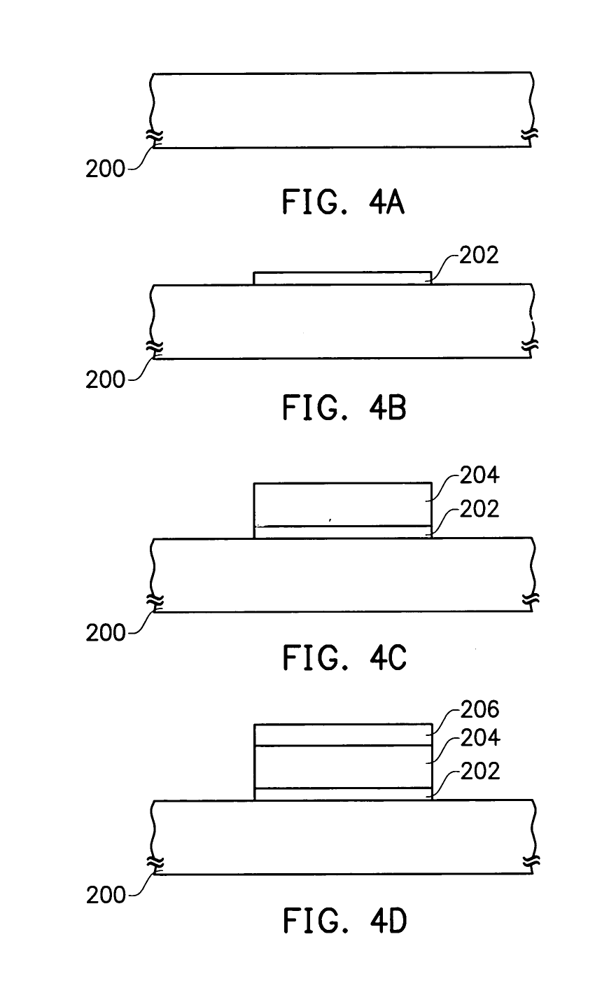

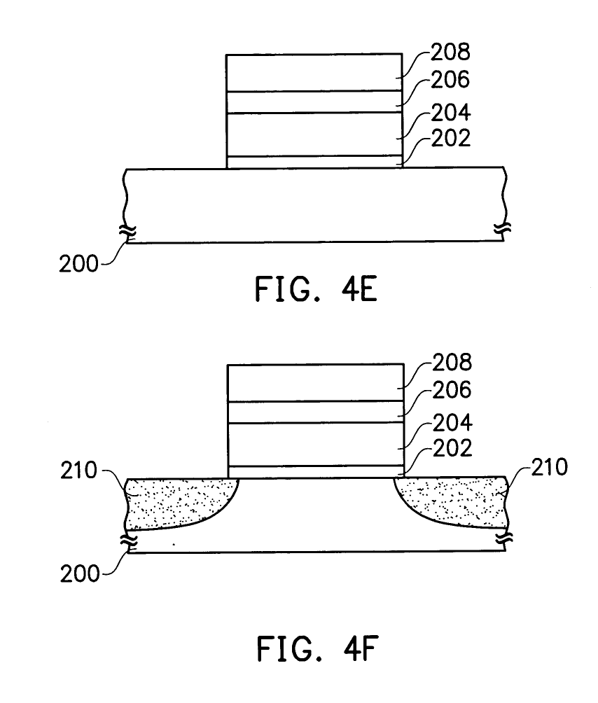

FIGS. 4A-4F are schematic cross sectional drawings showing a process flow of a method of fabricating a memory device according to a preferred embodiment of the present invention. Referring to FIG. 4A, first a substrate 200 is provided. Wherein, the forbidden gap of the substrate 200 is larger than that of silicon. The material of the substrate 200 can be, for example, SiₓC₁₋ₓ or SiₓGe_{y}C_{z}. The substrate 200 can be deposited by chemical vapor deposition method over the entire wafer (not shown), for example. The substrate 200 can be in situ doped during deposition, or doped during a subsequent ion-implantation step to decide the conductive type. The conductive doping can be n-type or p-type. In one embodiment, for example, substrate 200 is deposited using a low-pressure chemical vapor deposition (LPCVD) method, a rapid thermal chemical vapor deposition method (RTCVD), a plasma-enhanced chemical vapor deposition (PECVD) method, or a microwave chemical vapor deposition method known to those skilled in the art.

The substrate 200 also can be deposited by a low-temperature molecular beam epitaxy method. In an embodiment, plasma-enhanced molecular beam epitaxy (PEMBE) is used to form the substrate 200, for example, by using electron cyclotron resonance (ECR) plasma during molecular beam epitaxy (MBE). The C flux/C and Ga fluxes are supplied to a silicon wafer (not shown). The silicon wafer is heated to a lower temperature (such as to approximately 550 degrees Celsius) for growth of a thin SiₓC₁₋ₓ/SiₓGe_{y}C_{z} layer. The temperature is then increased (such as to approximately 800 degrees Celsius) to form the remainder of the SiₓC₁₋ₓ/SiₓGe_{y}C_{z} film.

The substrate 200 also can be formed using other technology such as, for example, a laser irradiation decomposition method, or a reactive magnetic sputtering method. In addition to SiₓC₁₋ₓ or SiₓGe_{y}C_{z}, the material of the substrate 200 can be, for example, GeP, GeAs, ZnSe, CdTe, AlAs, InP, CdS, or GaN.

Referring to FIG. 4B, an insulation layer 202 is formed over the substrate 200. Wherein, the insulation layer 202 can serve as a tunneling dielectric layer of a non-volatile read-only memory, for example. The material of the insulation layer 202 can be, for example, silicon oxide, silicon nitride, or other suitable dielectric materials. The method of forming the insulation layer 202 can be, for example, a chemical vapor deposition (CVD) method or other suitable processes.

Referring to FIG. 4C, a charge storage layer 204 is formed over the insulation layer 202. Wherein, the material of the charge storage layer 204 varies with the type of the memory device. For a non-volatile read-only memory with a floating gate, the material of the charge storage layer 204 can be, for example, polysilicon which can be formed by a CVD method or other suitable processes. In addition, for a non-volatile read-only memory with a charge-trap layer, the material of the charge storage layer 204 can be silicon nitride which can be formed by a CVD method.

Referring to FIG. 4D, an insulation layer 206 is formed over the charge storage layer 204. The material of the insulation layer 206 can be, for example, silicon nitride, silicon oxide, silicon oxide/silicon nitride/silicon oxide (O/N/O), or other suitable materials which can be formed by a CVD method or other suitable processes.

Referring to FIG. 4E, a gate electrode layer 208 is formed over the insulation layer 206. Wherein, the gate electrode layer 208, the insulation layer 206, the charge storage layer 204, and the insulation layer 202 constitute a stacked structure. Wherein, the material of the gate electrode layer 208 can be, for example, polysilicon or metal which can be formed by a CVD method or other suitable processes.

Finally, referring to FIG. 4F, source/drain regions 210 are formed in the substrate 200 adjacent to two sides of the stacked structure. Wherein, the method of forming the source/drain regions 210 can be, for example, an ion implantation method.

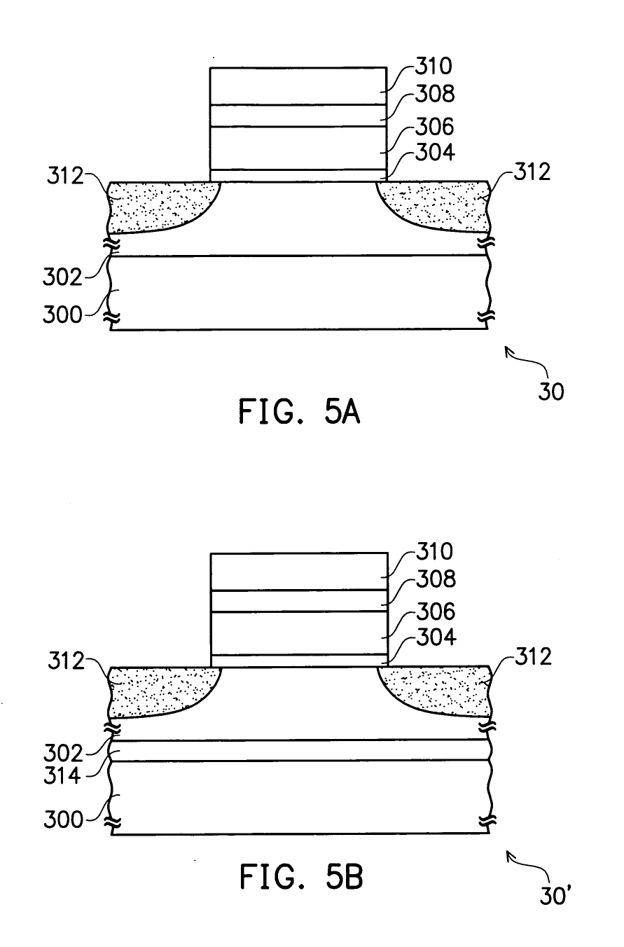

FIG. 5A is a schematic cross sectional view showing a memory device according to another preferred embodiment of the present invention. Referring to FIG. 5A, the memory device 30 of this embodiment comprises a semiconductor layer 300, a substrate 302, an insulation layer 304, a charge storage layer 306, an insulation layer 308, a gate electrode layer 310, and source/drain regions 312. In this embodiment, the substrate 302 is disposed over the semiconductor layer 300. The insulation layer 304 is disposed over the substrate 302. The charge storage layer 306 is disposed over the insulation layer 304. The insulation layer 308 is disposed over the charge storage layer 306. The gate electrode layer 310 is disposed over the insulation layer 308. Wherein, the gate electrode layer 310, the insulation layer 308, the charge storage layer 306, and the insulation layer 304 constitute a stacked structure. The source/drain regions 312 are disposed in the substrate 302 adjacent to two sides of the stacked structure. Note that the forbidden gap of the substrate 302 is larger than that of silicon in this embodiment.

FIG. 5B is a schematic cross sectional view showing a memory device according to a preferred embodiment of the present invention. Referring to FIGS. 5A and 3B, the memory device 30′ of this embodiment is similar to the memory device 30 in FIG. 5A. What is different is that, in this embodiment, an insulation layer 314 is disposed between the substrate 302 and the semiconductor layer 300. The disposition of the insulation layer 314 depends on the manufacturer's need and is optional.

The materials of these film layers of the memory device 30 will be described below with the following process flow.

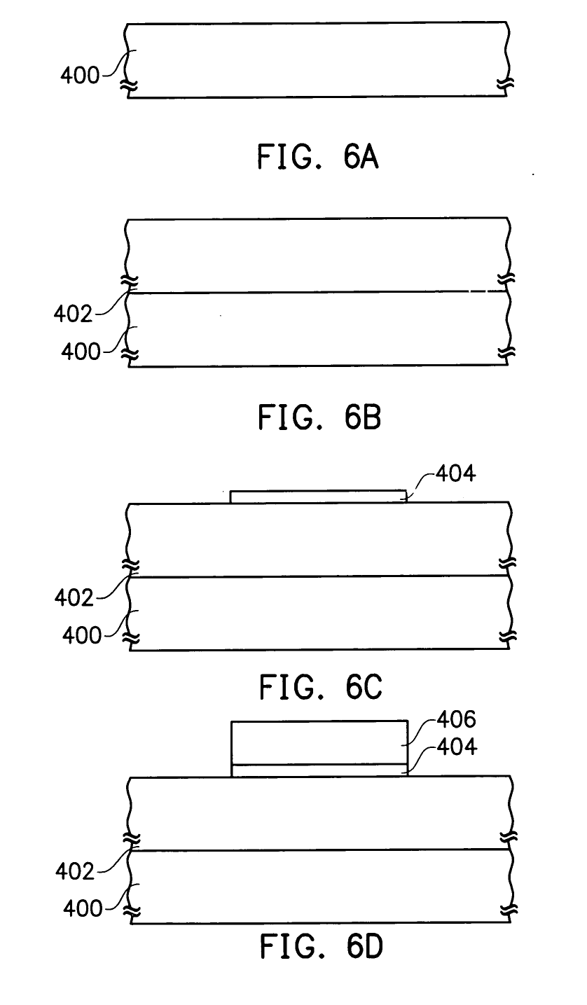

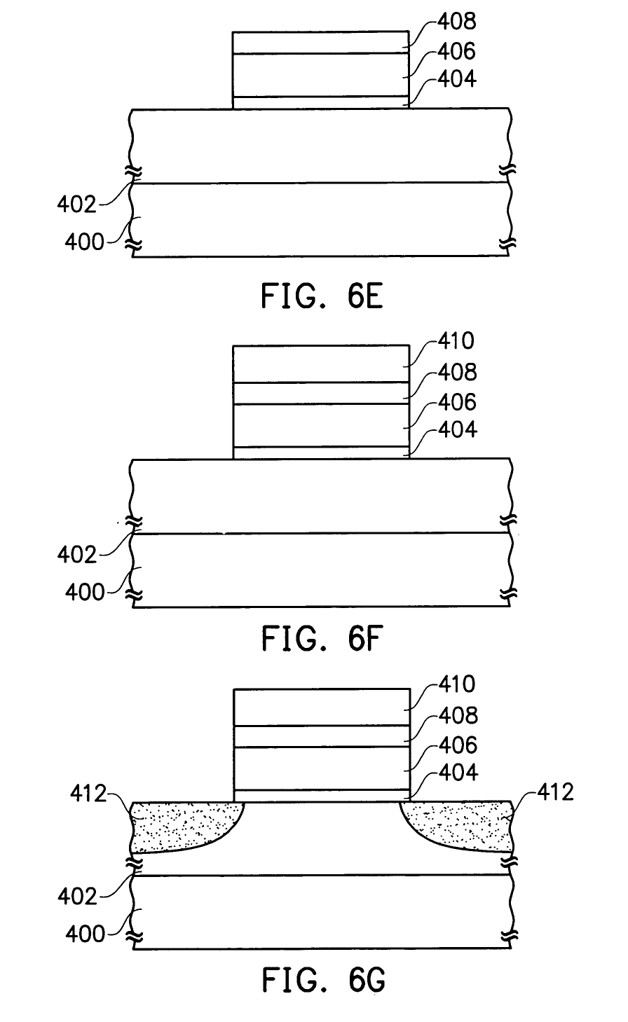

FIGS. 6A-6G are schematic cross sectional drawings showing a process flow of a method of fabricating a memory device according to another preferred embodiment of the present invention. Referring to FIG. 6A, first a semiconductor layer 400 is provided. Wherein, the material of the semiconductor layer can be, for example, Si or Ge.

Referring to FIG. 6B, the substrate 402 is formed over the semiconductor layer 400. Wherein, the forbidden gap of the substrate 402 is larger than that of silicon. The material of the substrate 402 can be, for example, SiₓC₁₋ₓ or SiₓGe_{y}C_{z}. The method of forming the substrate 402 can be the method described in FIG. 4A, for example, the substrate 402 can be formed by a low-pressure chemical vapor deposition (LPCVD) method, a rapid thermal chemical vapor deposition method (RTCVD), a plasma-enhanced chemical vapor deposition (PECVD) method, a microwave chemical vapor deposition method, a laser irradiation decomposition method, a low-temperature molecular beam epitaxy method, or a reactive magnetic sputtering method. In addition to SiₓC₁₋ₓ or SiₓGe_{y}C_{z}, the material of the substrate 402 can be, for example, GeP, GeAs, ZnSe, CdTe, AlAs, InP, CdS, or GaN.

Referring to FIG. 6C, an insulation layer 404 is formed over the substrate 402. Wherein, the insulation layer 404 can serve as a tunneling dielectric layer of a non-volatile read-only memory, for example. The material of the insulation layer 404 can be, for example, silicon oxide, silicon nitride, or other suitable dielectric materials. The method of forming the insulation layer 404 can be, for example, a chemical vapor deposition (CVD) method or other suitable processes.

Referring to FIG. 6D, a charge storage layer 406 is formed over the insulation layer 404. Wherein, the material of the charge storage layer 406 varies with the type of the memory device. For a non-volatile read-only memory with a floating gate, the material of the charge storage layer 406 can be, for example, polysilicon which can be formed by a CVD method or other suitable processes. In addition, for a non-volatile read-only memory with a charge-trap layer, the material of the charge storage layer 406 can be silicon nitride which can be formed by a CVD method.

Referring to FIG. 6E, an insulation layer 408 is formed over the charge storage layer 406. The material of the insulation layer 408 can be, for example, silicon nitride, silicon oxide, silicon oxide/silicon nitride/silicon oxide (O/N/O), or other suitable materials which can be formed by a CVD method or other suitable processes.

Referring to FIG. 6F, a gate electrode layer 410 is formed over the insulation layer 408. Wherein, the gate electrode layer 410, the insulation layer 408, the charge storage layer 406, and the insulation layer 404 constitute a stacked structure. In this embodiment, the material of the gate electrode layer 410 can be, for example, polysilicon or metal which can be formed by a CVD method or other suitable processes.

Finally, referring to FIG. 6G, source/drain regions 412 are formed in the substrate 402 adjacent to two sides of the stacked structure. Wherein, the method of forming the source/drain regions 412 can be, for example, an ion implantation method.

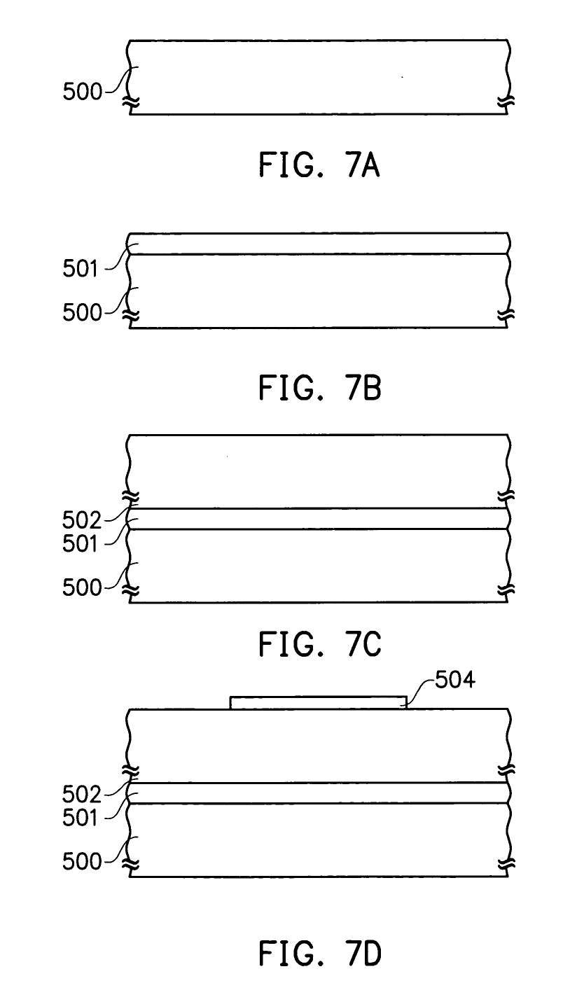

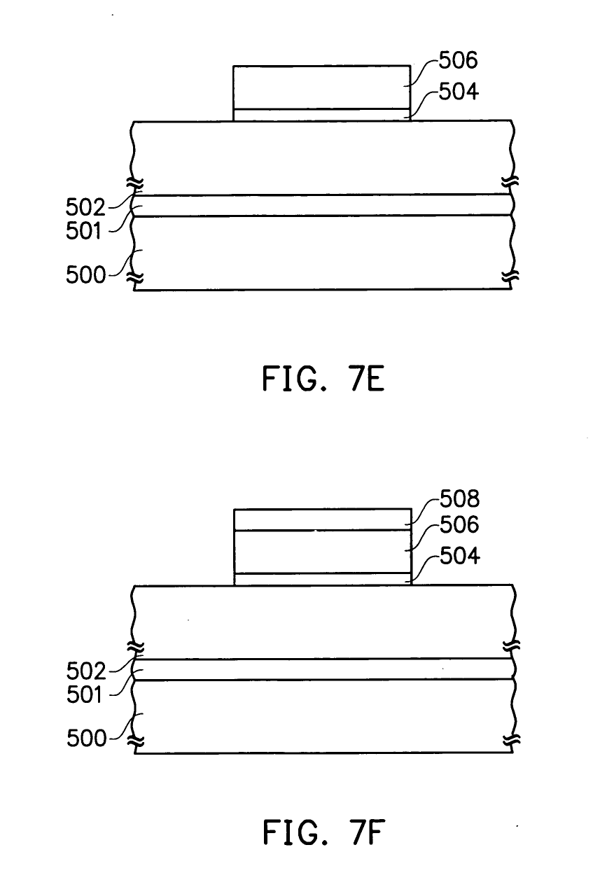

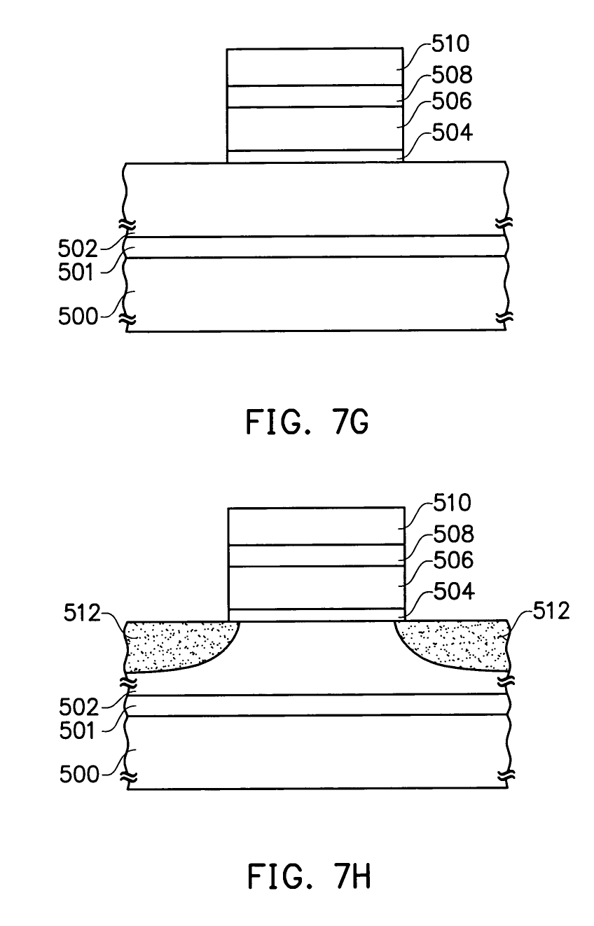

FIGS. 7A-7H are schematic cross sectional drawings showing a process flow of a method of fabricating a memory device according to a preferred embodiment of the present invention. Referring to FIG. 7A, first a semiconductor layer 500 is provided. Referring to FIG. 7B, an insulation layer 501 is formed over the semiconductor layer 500. Referring to FIG. 7C, a substrate 502 is formed over the insulation layer 501.

Referring to FIGS. 7D-7H, the process flow of this embodiment is similar to that shown in FIGS. 6B-6G. The insulation layer 504, the charge storage layer 506, the insulation layer 508, and the gate electrode layer 510 are sequentially formed over the substrate 502. The source/drain regions 512 are formed in the substrate 502 adjacent to the stacked structure.

Accordingly, because the substrate material of the present invention has a larger forbidden gap than that of silicon, the energy barrier between the substrate and the first insulation layer of the present invention is smaller. When the memory device is programmed or erased, electrons or holes can be easily injected into the charge storage layer from the substrate, or into the substrate from the charge storage layer. Accordingly, the operational speed of the memory device can be improved.

In addition, since the substrate material of the present invention has a larger forbidden gap than that of silicon, the anode hot electron/hole impact effect to the first insulation layer, i.e., the tunneling dielectric layer, can be reduced, while the FN tunneling method is applied to the memory device. The reliability of the memory device is thus enhanced.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A memory device, comprising:
a substrate, wherein a forbidden gap of the substrate is larger than a forbidden gap of silicon;
a first insulation layer disposed over the substrate;
a charge storage layer disposed over the first insulation layer;
a second insulation layer disposed over the charge storage layer;
a gate electrode layer disposed over the second insulation layer, wherein the gate electrode layer, the second insulation layer, the charge storage layer, and the first insulation layer constitute a stacked structure; and
source/drain regions disposed in the substrate adjacent to two sides of the stacked structure.

2. The memory device of claim 1, wherein a material of the substrate comprises SiₓC₁₋ₓ or SiₓGe_{y}C_{z}.

3. The memory device of claim 1, wherein a material of the substrate comprises GeP, GeAs, ZnSe, CdTe, AlAs, InP, CdS, or GaN.

4. A method of fabricating a memory device, comprising:
providing a substrate, wherein a forbidden gap of the substrate is larger than a forbidden gap of silicon;
forming a first insulation layer over the substrate;
forming a charge storage layer over the first insulation layer;
forming a second insulation layer over the charge storage layer;
forming a gate electrode layer over the second insulation layer, wherein the gate electrode layer, the second insulation layer, the charge storage layer, and the first insulation layer constitute a stacked structure; and
forming source/drain regions in the substrate adjacent to two sides of the stacked structure.

5. The method of fabricating a memory device of claim 4, wherein a material of the substrate comprises SiₓC₁₋ₓ or SiₓGe_{y}C_{z}.

6. The method of fabricating a memory device of claim 5, wherein a method of forming the substrate comprises a low-pressure chemical vapor deposition (LPCVD) method, a rapid thermal chemical vapor deposition method (RTCVD), a plasma-enhanced chemical vapor deposition (PECVD) method, a microwave chemical vapor deposition method, a laser irradiation decomposition method, a low-temperature molecular beam epitaxy method, or a reactive magnetic sputtering method.

7. The method of fabricating a memory device of claim 4, wherein a material of the substrate comprises GeP, GeAs, ZnSe, CdTe, AlAs, InP, CdS, or GaN.

8. A memory device, comprising:
a semiconductor layer;
a substrate disposed over the semiconductor layer, wherein a forbidden gap of the substrate is larger than a forbidden gap of silicon;
a first insulation layer disposed over the substrate;
a charge storage layer disposed over the first insulation layer;
a second insulation layer disposed over the charge storage layer;
a gate electrode layer disposed over the second insulation layer, wherein the gate electrode layer, the second insulation layer, the charge storage layer, and the first insulation layer constitute a stacked structure; and
source/drain regions disposed in the substrate adjacent to two sides of the stacked structure.

9. The memory device of claim 8, wherein a material of the semiconductor layer comprises Si or Ge.

10. The memory device of claim 8, wherein an insulation layer is disposed between the substrate and the semiconductor layer.

11. The memory device of claim 8, wherein a material of the substrate comprises SiₓC₁₋ₓ or SiₓGe_{y}C_{z}.

12. The memory device of claim 8, wherein a material of the substrate comprises GeP, GeAs, ZnSe, CdTe, AlAs, InP, CdS, or GaN.

13. A method of fabricating a memory device, comprising:
providing a semiconductor layer;
forming a substrate over the semiconductor layer, wherein a forbidden gap of the substrate is larger than a forbidden gap of silicon;
forming a first insulation layer over the substrate;
forming a charge storage layer over the first insulation layer;
forming a second insulation layer over the charge storage layer;
forming a gate electrode layer over the second insulation layer, wherein the gate electrode layer, the second insulation layer, the charge storage layer, and the first insulation layer constitute a stacked structure; and
forming source/drain regions in the substrate adjacent to two sides of the stacked structure.

14. The method of fabricating a memory device of claim 13, wherein a material of the semiconductor layer comprises Si or Ge.

15. The method of fabricating a memory device of claim 13, further comprising:
forming an insulation layer over the semiconductor layer; and
forming the substrate over the insulation layer.

16. The method of fabricating a memory device of claim 13, wherein a material of the substrate comprises SiₓC₁₋ₓ or SiₓGe_{y}C_{z}.

17. The method of fabricating a memory device of claim 16, wherein a method of forming the substrate comprises a low-pressure chemical vapor deposition (LPCVD) method, a rapid thermal chemical vapor deposition method (RTCVD), a plasma-enhanced chemical vapor deposition (PECVD) method, a microwave chemical vapor deposition method, a laser irradiation decomposition method, a low-temperature molecular beam epitaxy method, or a reactive magnetic sputtering method.

18. The method of fabricating a memory device of claim 17, wherein a material of the substrate comprises GeP, GeAs, ZnSe, CdTe, AlAs, InP, CdS, or GaN.
